(19) United States
(12) Patent Application Publication
(10) Pub. No.: US 2024/0347258 A1
(43) Pub. Date: Oct. 17, 2024

(54) FILTER DEVICE AND RADIO-FREQUENCY FRONT END CIRCUIT INCORPORATING THE SAME

(71) Applicant: Murata Manufacturing Co., Ltd., Nagaokakyo-shi (JP)

(72) Inventor: Akira TANAKA, Nagaokakyo-shi (JP)

(21) Appl. No.: 18/753,119

(22) Filed: Jun. 25, 2024

Related U.S. Application Data
(63) Continuation of application No. PCT/JP2022/039128, filed on Oct. 20, 2022.

(30) Foreign Application Priority Data
Dec. 28, 2021 (JP) 2021-214463

(51) Int. Cl. H01F 27/28; H01F 27/29; H03H 7/01

(52) U.S. Cl. CPC H01F 27/2804; H01F 27/292; H03H 7/01; H01F 2027/2809

(57) ABSTRACT

A filter device includes a dielectric including a main surface, and a filter in the dielectric. The filter includes first and second inductors inside the dielectric. The first inductor includes a first coil with a winding axis corresponding to a normal direction to the main surface of the dielectric. The second inductor includes a second coil including flat-plate electrodes in the dielectric and extending linearly, and vias connected to the flat-plate electrodes and extending in a normal direction of the dielectric. In a plan view seen from the normal direction of the dielectric, an imaginary line does not intersect with an inner surface of the first coil, the imaginary line being drawn from a center position in an extending direction of the flat-plate electrodes in the second inductor to extend in a direction orthogonal or substantially orthogonal to the extending direction.

### CROSS REFERENCE TO RELATED APPLICATIONS

This application claims the benefit of priority to Japanese Patent Application No. 2021-214463 filed on Dec. 28, 2021 and is a Continuation Application of PCT Application No. PCT/JP2022/039128 filed on Oct. 20, 2022. The entire contents of each application are hereby incorporated herein by reference.

### BACKGROUND OF THE INVENTION

### 1. Field of the Invention

The present disclosure relates to filter devices and radio-frequency front end circuits including the same, and more particularly, to techniques to improve robustness against manufacturing variations in LC filters each including an inductor.

### 2. Description of the Related Art

Japanese Patent Laid-Open No. 2021-19304 discloses a diplexer including a low-pass circuit and a high-pass circuit. Each of the low-pass circuit and the high-pass circuit includes an LC filter including a plurality of inductors and a plurality of capacitors that are disposed inside a dielectric.

In a filter device such as a diplexer disclosed in Japanese Patent Laid-Open No. 2021-19304, an inductor included in each filter includes a planar coil having a winding axis corresponding to a normal direction of a dielectric, and/or a vertical coil formed of a plurality of vias extending in the normal direction of the dielectric and a flat-plate electrode connecting the vias.

In such a filter device, when an inductor included in each filter deviates from a design position due to manufacturing variations, desired filter characteristics may not be achieved.

### SUMMARY OF THE INVENTION

Example embodiments of the present invention improve robustness against manufacturing variations in filter devices.

A filter device according to an example embodiment of the present invention includes a dielectric including a main surface, and a first filter in the dielectric. The first filter includes a first inductor and a second inductor inside the dielectric. The first inductor is a first coil with a winding axis corresponding to a normal direction to the main surface of the dielectric. The second inductor is a second coil including a first flat-plate electrode in the dielectric and extending linearly, and a via connected to the first flat-plate electrode and extending in the normal direction of the dielectric. In a plan view seen from the normal direction to the main surface of the dielectric, a first imaginary line does not intersect with an inner surface of the first coil, the first imaginary line being drawn from a center position in an extending direction of the first flat-plate electrode in the second inductor to extend in a direction orthogonal or substantially orthogonal to the extending direction.

A filter device according to an example embodiment of the present invention includes a dielectric including a main surface, and a first filter and a second filter in the dielectric. The first filter includes a first passband. The second filter includes a second passband higher in frequency than the first passband. The first filter includes a first inductor and a second inductor inside the dielectric. The first inductor is a first coil with a winding axis corresponding to a normal direction to the main surface of the dielectric. The second inductor is a second coil including a first flat-plate electrode in the dielectric and extending linearly, and a via connected to the first flat-plate electrode and extending in a normal direction of the dielectric. In a plan view seen from the normal direction to the main surface of the dielectric, an imaginary line does not intersect with an inner surface of the first coil, the imaginary line being drawn from a center position in an extending direction of the first flat-plate electrode in the second inductor to extend in a direction orthogonal or substantially orthogonal to the extending direction.

In the filter devices according to example embodiments of the present invention, the inductors are arranged such that the winding axis direction of the second inductor included in a vertical coil (the second coil) does not intersect with the inner surface of the first inductor included in a planar coil (the first coil). Thus, even when the positions of the first and second inductors are slightly displaced due to manufacturing variations, magnetic coupling between the first and the second inductors is decreased. Therefore, the robustness against the manufacturing variations can be improved in the filter devices.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a block diagram of a communication apparatus including a radio-frequency front end circuit to which a filter device according to a first example embodiment of the present invention is applied.

FIG. 2 is an equivalent circuit diagram of the filter device according to the first example embodiment of the present invention.

FIG. 3 is an external view of the filter device according to the first example embodiment of the present invention.

FIG. 4 is a perspective view showing the inside of the filter device according to the first example embodiment of the present invention.

FIG. 5 is an exploded perspective view showing an example of a detailed structure of the filter device according to the first example embodiment of the present invention.

FIG. 6 is a diagram for illustrating structures of filter devices in the first example embodiment of the present invention, a first modification, and a comparative example, and variations in a resonance frequency resulting from manufacturing variations.

FIG. 7 is a diagram for illustrating an evaluation point of attenuation characteristics.

FIG. 8 is a diagram for illustrating the attenuation characteristics in the filter device in each of the first example embodiment of the present invention and the comparative example.

FIG. 9 is a diagram showing the attenuation characteristics of the filter device in the first example embodiment of the present invention.

FIG. 10 is an equivalent circuit diagram of a filter device according to a second example embodiment of the present invention.

FIG. 11 is a plan view of a first example of an arrangement in the filter device in the second example embodiment of the present invention.

FIG. 12 is a plan view of a second example of the arrangement in the filter device in the second example embodiment of the present invention.

FIG. 13 is a plan view of a third example of the arrangement in the filter device in the second example embodiment of the present invention.

### DETAILED DESCRIPTION OF THE EXAMPLE EMBODIMENTS

Hereinafter, example embodiments of the present disclosure will be described in detail with reference to the accompanying drawings, in which the same or corresponding portions are denoted by the same reference characters and will not be described repeatedly.

### First Example Embodiment

### Basic Configuration of Communication Apparatus

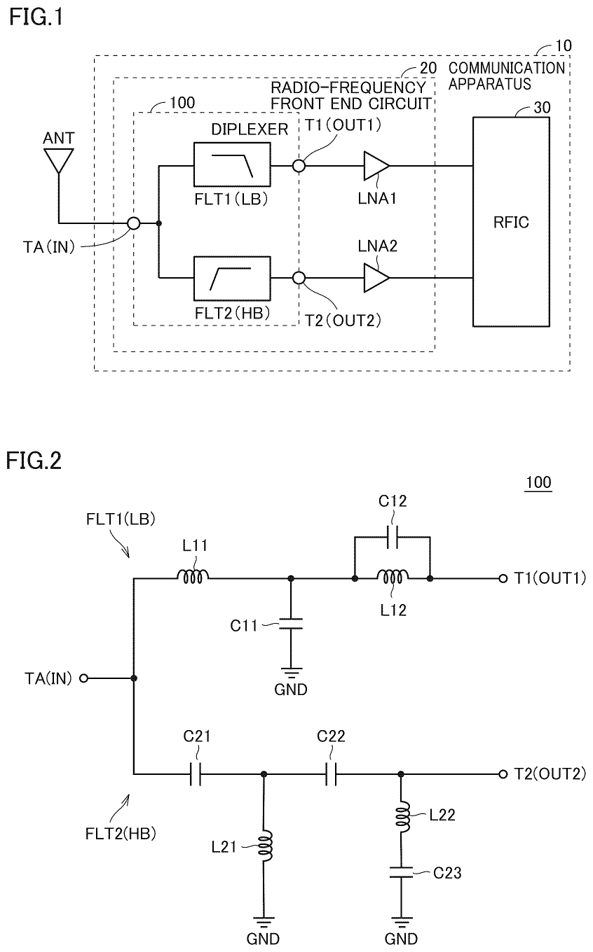

FIG. 1 is a block diagram of a communication apparatus 10 including a radio-frequency front end circuit 20 to which a filter device 100 according to a first example embodiment of the present invention is applied. Radio-frequency front end circuit 20 splits a radio-frequency signal received by an antenna apparatus ANT into a predetermined number of plurality of frequency bands and transmits the split signals to a subsequent processing circuit. Radio-frequency front end circuit 20 is used, for example, in a mobile terminal such as a mobile phone, a smartphone, or a tablet, or in a communication apparatus of a personal computer or the like having a communication function.

Referring to FIG. 1, communication apparatus 10 includes radio-frequency front end circuit 20 including filter device 100, and an RF signal processing circuit (hereinafter also referred to as an “RFIC”) 30. Radio-frequency front end circuit 20 shown in FIG. 1 is a reception front end circuit. Radio-frequency front end circuit 20 includes filter device 100 and amplifier circuits LNA1 and LNA2.

Filter device 100 is a diplexer including a filter FLT1 (a first filter) and a filter FLT2 (a second filter) having different frequency ranges as passbands. In the following description, filter device 100 may be referred to as a “diplexer”.

Filter FLT1 is connected between an antenna terminal TA, which is a common terminal, and a first terminal T1. Filter FLT1 is a low-pass filter having a frequency range in a low-band (LB) group as a passband and a frequency range in a high-band (HB) group as a non-passband. Filter FLT2 is connected between antenna terminal TA and a second terminal T2. Filter FLT2 is a high-pass filter having a frequency range in a high-band group as a passband and a frequency range in a low-band group as a non-passband. Filters FLT1 and FLT2 each may be configured as a bandpass filter.

Each of filters FLT1 and FLT2 allows passage of a radio-frequency signal corresponding to a passband of each filter among the radio-frequency signals having been received by antenna apparatus ANT. Thus, the signal received from antenna apparatus ANT is split into signals of a predetermined number of plurality of frequency bands.

Each of amplifier circuits LNA1 and LNA2 is a low-noise amplifier. Amplifier circuits LNA1 and LNA2 each amplify, with low noise, the radio-frequency signal that has passed through a corresponding filter, and transmit the amplified signal to RFIC 30.

RFIC 30 is an RF signal processing circuit that processes a radio-frequency signal transmitted and received by antenna apparatus ANT. Specifically, RFIC 30 performs signal processing by, for example, down-conversion or the like on the radio-frequency signal input from antenna apparatus ANT through a reception-side signal path of radio-frequency front end circuit 20, and then, outputs a reception signal generated by this signal processing to a baseband signal processing circuit (not shown).

When radio-frequency front end circuit 20 is used as a reception circuit as in FIG. 1, in filter device 100, antenna terminal TA defines and functions as an input terminal IN, and first terminal T1 and second terminal T2 define and function as a first output terminal OUT1 and a second output terminal OUT2, respectively. The radio-frequency front end circuit can also be used as a transmission circuit. In this case, each of first terminal T1 and second terminal T2 of filter device 100 defines and functions as an input terminal, and antenna terminal TA defines and functions as a common output terminal. In that case, as an amplifier included in the amplifier circuit, a power amplifier is used in place of a low-noise amplifier.

### Configuration of Filter Device

FIG. 2 is a diagram showing an example of an equivalent circuit in filter device (diplexer) 100 in FIG. 1. As described in FIG. 1, filter FLT1 is connected between antenna terminal TA and first terminal T1. Filter FLT2 is connected between antenna terminal TA and second terminal T2.

Filter FLT1 includes inductors L11 and L12 and a capacitor C12 that define a series arm circuit, and a capacitor C11 that defines a parallel arm circuit. Inductor L11 is connected to antenna terminal TA, and inductor L12 is connected between inductor L11 and first terminal T1. In other words, inductors L11 and L12 are connected in series between antenna terminal TA and first terminal T1. Capacitor C11 is connected between a ground terminal GND and a connection node between inductors L11 and L12. Capacitor C12 is connected in parallel with inductor L12. According to the configurations described above, filter FLT1 defines and functions as a low-pass filter that allows passage of a signal in a frequency band lower than a prescribed frequency. By an LC resonance circuit including the parallel circuit of capacitor C12 and inductor L12, an attenuation pole is defined by the vicinity of the high frequency side in the passband.

Filter FLT2 includes capacitors C21 and C22 that define a series arm circuit, and inductors L21 and L22 and a capacitor C23 that define a parallel arm circuit. Capacitors C21 and C22 are connected in series between antenna terminal TA and second terminal T2. Inductor L21 is connected between ground terminal GND and a connection node between capacitors C21 and C22. One end of inductor L22 is connected to second terminal T2. The other end of inductor L22 is connected to ground terminal GND through capacitor C23. According to the configurations described above, filter FLT2 defines and functions as a high-pass filter that allows passage of a signal in a frequency band higher than a prescribed frequency.

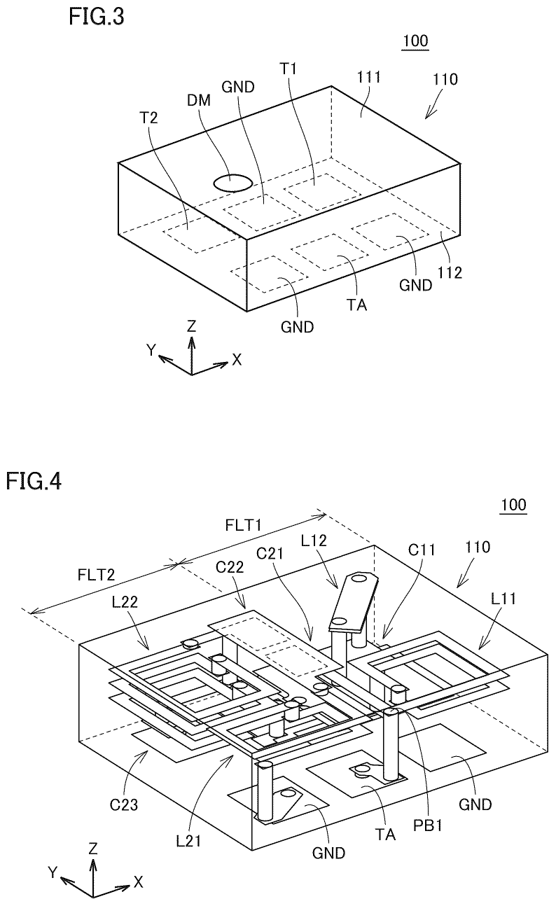

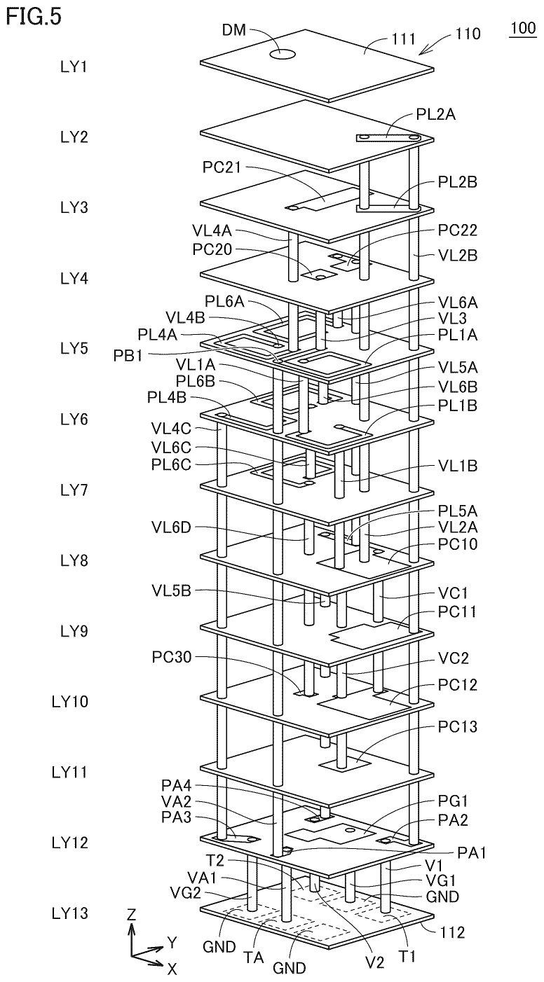

The following describes a detailed configuration of filter device 100 with reference to FIGS. 3 to 5. FIG. 3 is an external view of filter device 100 in FIG. 2, and FIG. 4 is a perspective view showing the inside of filter device 100. FIG. 5 is an exploded perspective view showing an example of a stack structure of filter device 100.

Referring to FIGS. 3 to 5, filter device 100 includes a dielectric 110 having a cuboid shape or a substantially cuboid shape and a plurality of dielectric layers LY1 to LY13 stacked in a prescribed direction. In dielectric 110, the direction in which the plurality of dielectric layers LY1 to LY13 are stacked is defined as a stacking direction. Each dielectric layer of dielectric 110 is made, for example, of ceramic such as low temperature co-fired ceramic (LTCC) or a resin. Inside dielectric 110, inductors and capacitors included in filters FLT1 and FLT2 are defined by a plurality of electrodes provided in each dielectric layer and a plurality of vias provided between the dielectric layers. FIGS. 3 to 5 do not show a dielectric in dielectric 110 and only show wiring patterns, vias, and conductors of terminals provided therein. In the following, for ease of description, an explanation will be provided with regard to an example case in which dielectric 110 has a multilayer structure as described above, but dielectric 110 may have a single-layer structure.

The “via” used herein refers to a conductor provided in a dielectric layer to establish a connection between electrodes provided in different dielectric layers. The via is made, for example, using a conductive paste, plating, and/or a metal pin. In the following description, a “Z-axis direction” denotes a direction in which dielectric layers LY1 to LY13 are stacked in dielectric 110, an “X-axis direction” denotes a direction perpendicular or substantially perpendicular to the Z-axis direction and extending along a long side of dielectric 110, and a “Y-axis direction” denotes a direction extending along a short side of dielectric 110. In the following description, the positive direction along the Z axis in each figure may be referred to as an upper side, and the negative direction along the Z axis in each figure may be referred to as a lower side.

Dielectric 110 includes an upper surface 111 (a first main surface) and a lower surface 112 (a second main surface). Upper surface 111 (dielectric layer LY1) of dielectric 110 includes a directional mark DM to specify the direction of filter device 100. As shown in FIG. 3, lower surface 112 (dielectric layer LY13) of dielectric 110 includes antenna terminal TA, first terminal T1, second terminal T2, and ground terminal GND as external terminals to connect filter device 100 to external devices. The external terminals, each of which is a flat plate-shaped electrode, are, for example, land grid array (LGA) terminals regularly arranged on lower surface 112 of dielectric 110. As shown in FIG. 4, schematically, filter FLT1 on the low-band side is disposed in a right-side portion (in the positive direction along the X axis) in dielectric 110, and filter FLT2 on the high-band side is disposed in a left side portion (in the negative direction along the X axis) in dielectric 110.

Antenna terminal TA disposed in dielectric layer LY13 of lower surface 112 is connected through vias VA1, VA2 and flat-plate electrode PA1 to a flat-plate electrode PL1A including a branch point PB1 between filters FLT1 and FLT2 in dielectric layer LY2. Via VA1 is connected to antenna terminal TA and flat-plate electrode PA1 that is provided in dielectric layer LY12. Via VA2 is connected to flat-plate electrode PA1 and flat-plate electrode PL1A.

The following first describes filter FLT1, which is a low-pass filter, in detail. As described above, branch point PB1 is disposed in a portion of strip-shaped flat-plate electrode PL1A wound around the axis (the Z axis) along the stacking direction of dielectric 110. Flat-plate electrode PL1A includes one end to which a via VL1A is connected. Flat-plate electrode PL1A is connected through via VL1A to one end of a strip-shaped flat-plate electrode PL1B provided in dielectric layer LY6. Flat-plate electrode PL1B has a C or substantially C shape and includes the other end to which a via VL1B is connected. Flat-plate electrode PL1B is connected through via VL1B to a capacitor electrode PC10 provided in dielectric layer LY8. Flat-plate electrodes PL1A and PL1B and vias VL1A and VL1B define inductor L11 in FIG. 2. Inductor L11 is a coil that is wound in the Z-axis direction. In the following description, a coil wound in the Z-axis direction, such as inductor L11, is also referred to as a “planar coil”.

Capacitor electrode PC10 is connected through vias VC1 and VC2 to a capacitor electrode PC12 provided in dielectric layer LY10. In a plan view of dielectric 110 seen from the stacking direction (in the normal direction to the main surface), each of capacitor electrodes PC10 and PC12 at least partially overlap with a capacitor electrode PC11 provided in dielectric layer LY9. Capacitor C12 in FIG. 2 is defined by the combined capacitance of the capacitor including capacitor electrodes PC10 and PC11, and the capacitor including capacitor electrodes PC11 and PC12.

Capacitor electrode PC11 is connected through a via VL2B to a flat-plate electrode PA2 provided in dielectric layer LY12. Flat-plate electrode PA2 is connected through via V1 to first terminal T1 disposed in dielectric layer LY13 of lower surface 112 of dielectric 110. Further, capacitor electrode PC11 is connected through via VL2B also to one end of a linear-shaped flat-plate electrode PL2A provided in dielectric layer LY2 and one end of a linear-shaped flat-plate electrode PL2B provided in dielectric layer LY3. The other end of each of flat-plate electrodes PL2A and PL2B is connected through a via VL2A to capacitor electrode PC10 of dielectric layer LY8. Flat-plate electrodes PL2A and PL2B and vias VL2A and VL2B define inductor L12 in FIG. 2. Inductor L12 is a coil included in a linearly-extending flat-plate electrode and a plurality of vias, the coil having a winding axis intersecting with the Z-axis direction. In the following description, a coil having a configuration such as that of inductor L12 is also referred to as a “vertical coil”.

Inductor L11 preferably has a longer line length than inductor L12. In general, a vertical coil has a higher Q value and smaller loss than a planar coil, but is disadvantageous in obtaining a large reactance value. Thus, inductor L12 as a vertical coil having a high Q value is configured to have a relatively short line length and inductor L11 as a planar coil is configured to have a relatively long line length, thus making it possible to provide an inductance value required for filter FLT1 while maintaining a high Q value.

Further, in the filter on the low-band side in the diplexer, the inductance value on the input side is preferably set as high as possible in order to block the signal on the high-band side. Thus, in the present example embodiment, inductor L11 having a relatively large inductance value is connected to antenna terminal TA.

Further, for the vertical coil, the reactance value of the vertical coil is preferably set as small as possible in order to obtain steep characteristics in the vicinity of the passband. Thus, the number of turns of inductor L12 is preferably, for example, one turn or less.

Via VC2 through which capacitor electrodes PC10 and PC12 are connected is also connected to a capacitor electrode PC13 provided in dielectric layer LY11. In a plan view of dielectric 110 seen from the stacking direction, capacitor electrode PC13 partially overlaps with a ground electrode PG1 provided in dielectric layer LY12. Ground electrode PG1 is connected through a via VG1 to ground terminal GND disposed in dielectric layer LY13 of lower surface 112 of dielectric 110. Capacitor electrode PC13 and ground electrode PG1 define capacitor C11 in FIG. 2.

Then, filter FLT2 as a high-pass filter will be described in detail. The other end of flat-plate electrode PL1A at which branch point PB1 is located is connected through a via VL3 to a capacitor electrode PC20 provided in dielectric layer LY4. In a plan view of dielectric 110 seen from the stacking direction, capacitor electrode PC20 partially overlaps with a capacitor electrode PC21 provided in dielectric layer LY3. Capacitor electrodes PC20 and PC21 define capacitor C21 in FIG. 2.

Further, in dielectric layer LY4, a capacitor electrode PC22 partially overlaps with capacitor electrode PC21 provided in dielectric layer LY3 in a plan view of dielectric 110 seen from the stacking direction. Capacitor electrode PC22 is connected through a via VL5 to one end of a strip-shaped flat-plate electrode PL5A provided in dielectric layer LY8. The other end of flat-plate electrode PL5A is connected to a via VL5B, and connected through via VL5B to a flat-plate electrode PA4 provided in dielectric layer LY12. Flat-plate electrode PA4 is connected through a via V2 to second terminal T2 disposed in dielectric layer LY13 of lower surface 112 of dielectric 110. Capacitor electrodes PC21 and PC22 define capacitor C22 in FIG. 2.

Capacitor electrode PC22 is connected through a via VL6A also to one end of a strip-shaped flat-plate electrode PL6A that is provided in dielectric layer LY5 and wound around the Z axis. Flat-plate electrode PL6A includes the other end to which a via VL6B is connected. Flat-plate electrode PL6A is connected through via VL6B to one end of a strip-shaped flat-plate electrode PL6B that is provided in dielectric layer LY6 and wound around the Z axis. Flat-plate electrode PL6B includes the other end connected to a via VL6C. Flat-plate electrode PL6B is connected through via VL6C to one end of a strip-shaped flat-plate electrode PL6C that is provided in dielectric layer LY7 and wound around the Z axis. Flat-plate electrode PL6C includes the other end connected to a via VL6D. Flat-plate electrode PL6C is connected through via VL6D to a capacitor electrode PC30 provided in dielectric layer LY10. Flat-plate electrodes PL6A to PL6C and vias VL6A to VL6D define inductor L22 in FIG. 2.

In a plan view of dielectric 110 seen from the stacking direction, capacitor electrode PC30 partially overlaps with ground electrode PG1 provided in dielectric layer LY12. Capacitor electrode PC30 and ground electrode PG1 define capacitor C23 in FIG. 2.

Further, capacitor electrode PC21 is connected through a via VL4A to one end of a strip-shaped flat-plate electrode PL4A that is provided in dielectric layer LY5 and wound around the Z axis. Flat-plate electrode PL4A includes the other end connected through a via VL4B to one end of strip-shaped flat-plate electrode PL4B provided in dielectric layer LY6. Flat-plate electrode PL4B has an L or substantially L shape and includes the other end connected to a via VL4C. Via VL4C is connected to a flat-plate electrode PA3 provided in dielectric layer LY12. Flat-plate electrode PA3 is connected through a via VG2 to ground terminal GND disposed in dielectric layer LY13 of lower surface 112 of dielectric 110. Flat-plate electrodes PL4A, PL4B, and PA3 and vias VL4A to VL4C, and VG2 define inductor L21 in FIG. 2.

Variations in Characteristics Resulting from Manufacturing Variations

In recent years, due to an increase in frequency bands to be used, there may be a demand for a diplexer with a small band gap in which a passband on the high-band side and a passband on the low-band side are close to each other. In this case, for each band, steepness of attenuation in a non-passband in the vicinity of each passband is required. For example, when a frequency band is about 2.3 GHz band on the high-band side and about 2.2 GHz band on the low-band side, a frequency margin of about 20 MHz is required for each band.

The frequency bandwidth and the amount of attenuation in each band are significantly influenced by the resonance frequency in each filter included in a diplexer. Therefore, in order to stably achieve the requirement for a narrow band gap as described above, it is important to reduce variations in the resonance frequency.

In filter device 100 as described above, each of inductors L21 and L22 included in filter FLT2 on the high-band side is a planar coil having a winding axis corresponding to the Z-axis direction. On the other hand, in filter FLT1 on the low-band side, inductor L11 is a planar coil, and inductor L12 is a vertical coil defined by a via and a linear-shaped flat-plate electrode.

In this case, when both of a planar coil and a vertical coil are used as inductors as in filter FLT1 on the low-band side, if the winding axis direction of the vertical coil corresponds to the direction of the planar coil, magnetic coupling occurs between the planar coil and the vertical coil. In this case, if the positional relationship between the planar coil and the vertical coil undergoes a slight positional deviation from the design values due to the processing accuracy during formation of vias or due to distortion or the like occurring during pressing of the stacked dielectrics, the magnetic coupling between the two coils is easily changed, which results in a deviation also in the resonance frequency of the filter. In this case, there is a possibility that a desired passband width and attenuation amount cannot be achieved.

Thus, in the present first example embodiment, in the filter in which a planar coil and a vertical coil are used as inductors, these two coils are arranged such that the winding axis of the vertical coil (i.e., the normal direction to an imaginary plane formed by a via and a flat-plate electrode) does not intersect with the planar coil in a plan view of the filter seen from the winding axis direction of the planar coil. In other words, the two coils are arranged such that no magnetic coupling occurs between these coils. In such a configuration, the magnetic coupling between the two coils is weak or does not occur. Thus, even if manufacturing variations cause a deviation in the positional relationship between the planar coil and the vertical coil, fluctuations in magnetic coupling are less likely to occur. Therefore, variations in characteristics resulting from the manufacturing variations can be reduced or prevented.

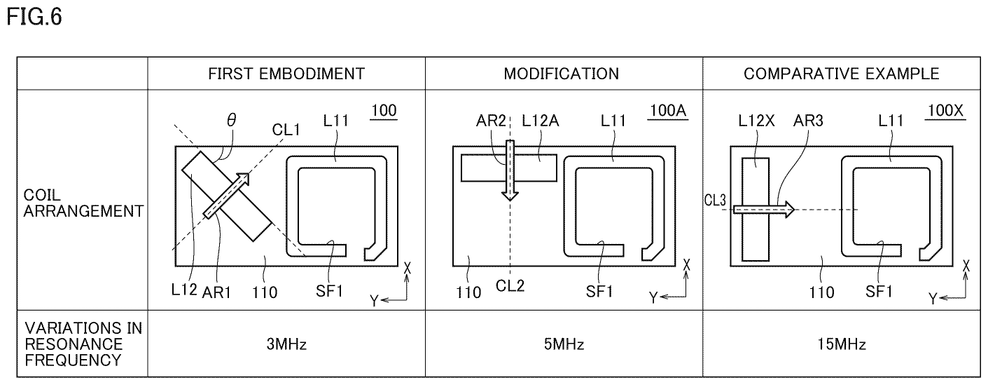

FIG. 6 is a diagram for illustrating variations in resonance frequency of a filter that are caused by a positional deviation of a vertical coil with regard to coil arrangements in filter device 100 in the first example embodiment and a filter device 100X in a comparative example. FIG. 6 shows an arrangement of each coil in a plan view of a filter portion on the low-band side in each filter device as seen from the stacking direction (the Z-axis direction) of dielectric 110, and each simulation value of the amount of variation in the resonance frequency when the via position in the vertical coil is shifted by about 20 μm in the winding axis direction. FIG. 6 also shows the case of a filter device 100A in a modification of the first example embodiment. In the diagram of each coil arrangement in FIG. 6, the configuration of the filter device on the high-band side is not shown.

In filter device 100 in the first example embodiment, inductor L12, which is a vertical coil, is inclined with respect to inductor L11, which is a planar coil. More specifically, for example, inductor L12 is disposed to satisfy the relationship of about 0°<θ≤about 45°, where θ is an angle between the direction in which inductors L11, L12 are arranged (i.e., the Y-axis direction) and the extending direction of flat-plate electrode PL2A that defines inductor L12. Filter device 100A in the modification is an example case in which an inductor L12A, which is a vertical coil, is disposed such that its winding direction extends in the X-axis direction, i.e., in which θ=about 0°. On the other hand, in filter device 100X in the comparative example, an inductor L12X, which is a vertical coil, is disposed such that its winding axis extends in the Y-axis direction. More specifically, the comparative example shows an example case in which θ=about 90°.

In the diagram showing the coil arrangements in the respective examples, arrows AR1, AR2, and AR3 respectively indicate the winding axis directions of inductors L12, L12A, and L12X, each of which is a vertical coil. In filter device 100X in the comparative example, an imaginary line CL3 intersects with inductor L11, in which imaginary line CL3 is drawn from a center position in the extending direction of the flat-plate electrode in inductor L12X to extend in the direction orthogonal or substantially orthogonal to the extending direction (i.e., in the winding axis direction). On the other hand, in filter devices 100 and 100A, each of respective imaginary lines CL1 and CL2 drawn to extend in the winding axis directions of respective inductors L12 and L12A does not intersect with an inner surface SF1 of inductor L11 and the body of inductor L11. The “inner surface” of inductor L11 refers to a surface of coil-shaped inductor L11 on its air core side. Further, the extending direction of each of imaginary lines CL1, CL2, and CL3 corresponds to a direction orthogonal or substantially orthogonal to the direction connecting two vias, which are connected to the linearly extending flat-plate electrode, in each inductor to extend through the center position between the two vias.

In such a configuration, when the position of each via is shifted by about 20 μm in the winding axis direction of each vertical coil (i.e., in the directions along arrows AR1, AR2, and AR3), the amount of variation in the resonance frequency is about 15 MHz in filter device 100X in the comparative example, but is reduced to about 3 MHz in filter device 100 in the first example embodiment and reduced to about 5 MHz in filter device 100A in the modification. In filter device 100A in the modification, it is considered that the distance between inductors L11 and L12A is shorter than that in filter device 100 in the first example embodiment, and thus, the degree of magnetic coupling is larger than that in filter device 100, so that the influence on the amount of variation is also increased.

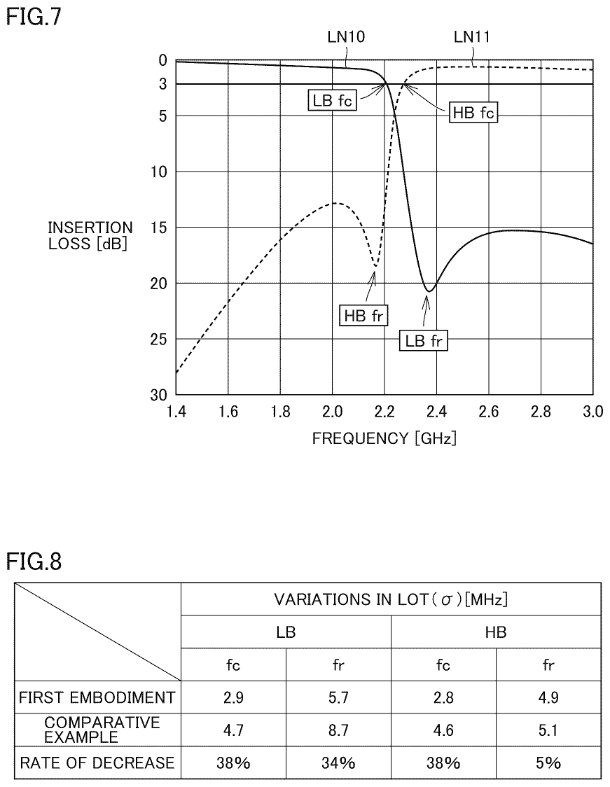

The following describes the attenuation characteristics in the filter device in each of the first example embodiment and the comparative example with reference to FIGS. 7 and 8. FIG. 7 is a diagram for illustrating an evaluation point of the attenuation characteristics. FIG. 8 is a diagram showing variations (standard deviations σ) of the frequency at each evaluation point in the manufacturing lots of the filter device in each of the first example embodiment and the comparative example. The number of each lot is 30.

In FIG. 7, a solid line LN10 indicates an insertion loss of the filter on the low-band (LB) side, and a dashed line LN11 indicates an insertion loss of the filter on the high-band (HB) side. As evaluation points, “fc” denotes a point at which the insertion loss is about 3 dB in a non-passband, and “fr” denotes a position of the attenuation pole.

Referring to FIG. 8, on the low-band side, in filter device 100 in the first example embodiment, the variation of fc is about 2.9 MHZ, and the variation of fr is about 5.7 MHz. In filter device 100X in the comparative example, the variation of fc is about 4.7 MHz and the variation of fr is about 8.7 MHz. Thus, in the first example embodiment, the variation of fc decreases by about 38% and the variation of fr decreases by about 34% as compared with those in the comparative example.

On the high-band side, in filter device 100 in the first example embodiment, the variation of fc is about 2.8 MHz and the variation of fr is about 4.9 MHz. In filter device 100X in the comparative example, the variation of fc is about 4.6 MHz and the variation of fr is about 5.1 MHZ. Thus, in the first example embodiment, fc decreases by about 38% but fr decreases only by about 5% as compared with the comparative example. Basically, the positional deviation of the vertical coil on the low-band side has almost no influence on the filter characteristics on the high-band side. However, for example, when the characteristics of fc and fr on the low-band side shift toward the high-frequency side, the amount of attenuation on the high-band side decreases, and the amount of leakage of the signal on the high-band side toward the low-band side increases. Then, the current to flow toward the high-band side decreases, and fc on the high-band side changes. Thus, it is considered that the variations in characteristics of fc on the high-band side also decrease due to reduction or prevention of the variations in characteristics on the low-band side.

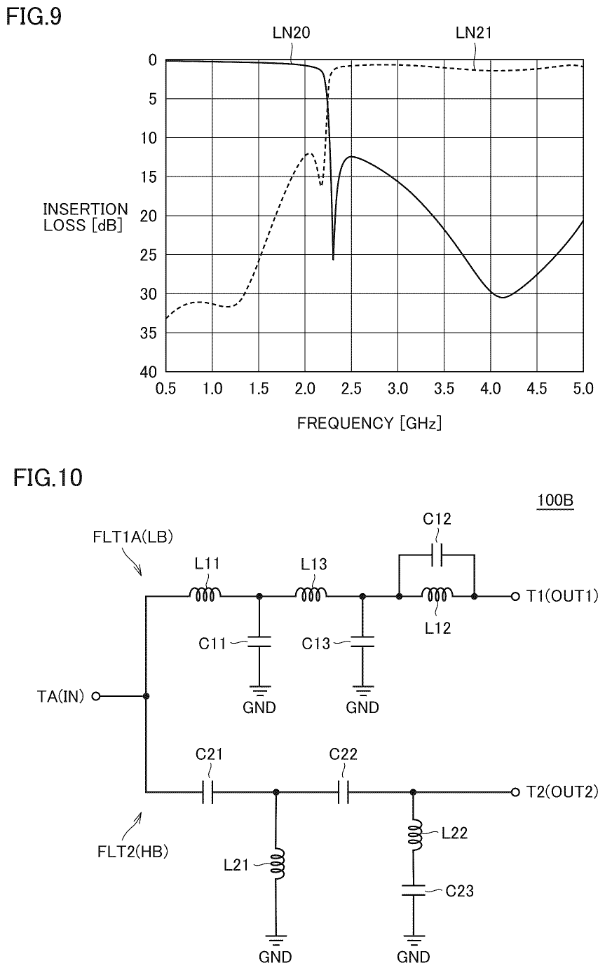

FIG. 9 is a diagram showing the attenuation characteristics of filter device 100 in the first example embodiment. In FIG. 9, a solid line LN20 indicates an insertion loss of filter FLT1 on the low-band side, and a dashed line LN21 indicates an insertion loss of filter FLT2 on the high-band side. As shown in FIG. 9, in filter FLT1 on the low-band side, the amount of attenuation at the attenuation pole is larger than that on the high-band side, and a steep attenuation characteristic is implemented.

As described above, in the filter device including a filter including a planar coil and a vertical coil as inductors, the imaginary line drawn to extend in the winding axis direction of the vertical coil is positioned so as not to intersect with at least the inner surface of the planar coil, thus making it possible to reduce the variations in characteristics with respect to the positional deviation of the vertical coil. Therefore, the robustness against the manufacturing variations can be improved.

In the above explanation, a planar coil and a vertical coil are used in combination in filter FLT1 on the low-band side, but the features of the present disclosure are applicable also in the case in which a planar coil and a vertical coil are used in combination in filter FLT2 on the high-band side.

“Filter FLT1” and “filter FLT2” in the present example embodiment correspond to the “first filter” and the “second filter”, respectively. “Inductor L11” and “inductor L12” in the first example embodiment correspond to the “first inductor” and the “second inductor”, respectively. “Fat-plate electrodes PL2A and PL2B” in the first example embodiment correspond to the “first flat-plate electrode”. The “planar coil” and the “vertical coil” in the present first example embodiment correspond to the “first coil” and the “second coil”, respectively.

### Second Example Embodiment

The first example embodiment has been described with regard to the arrangement of inductors in the case in which two inductors are included in the filter on the low-band side of the diplexer. A second example embodiment of the present invention will be described with regard to a case in which three inductors are included in the filter on the low-band side.

FIG. 10 is an equivalent circuit diagram of a filter device 100B according to the second example embodiment. Filter device 100B has a configuration in which filter FLT1 on the low-band side in filter device 100 in the first example embodiment shown in FIG. 2 is replaced with a filter FLT1A. Filter FLT1A further includes an inductor L13 and a capacitor C13 in addition to the configuration of filter FLT1 in the first example embodiment. In filter device 100B in FIG. 10, the same or corresponding elements as those of filter device 100 in FIG. 2 will not be described repeatedly.

Referring to FIG. 10, in filter FLT1A, inductor L13 is connected in series between inductors L11 and L12 in filter FLT1. Also, capacitor C13 is disposed between ground terminal GND and a connection node between inductors L12 and L13.

In this way, the configuration including three inductors also requires decrease of the magnetic coupling between the inductors in order to prevent or decrease the variations in characteristics resulting from manufacturing variations, as described in the first example embodiment. Thus, in filter FLT1A, among the three inductors, inductors L12 and L13 are each a vertical coil, and inductor L11 is a planar coil. Then, inductors L11, L12, and L13 are arranged such that the winding axes of inductors L12 and L13 each defined as a vertical coil do not intersect with the inner surface of inductor L11 defined as a planar coil, in a plan view of the filter device. Further, inductors L12 and L13 are arranged such that the winding axis of one of inductors L12 and L13 does not intersect with the other of inductors L12 and L13.

The above-described arrangement of inductors in filter FLT1A makes it possible to reduce or prevent variations in filter characteristics of filter FLT1A even when manufacturing variations occur.

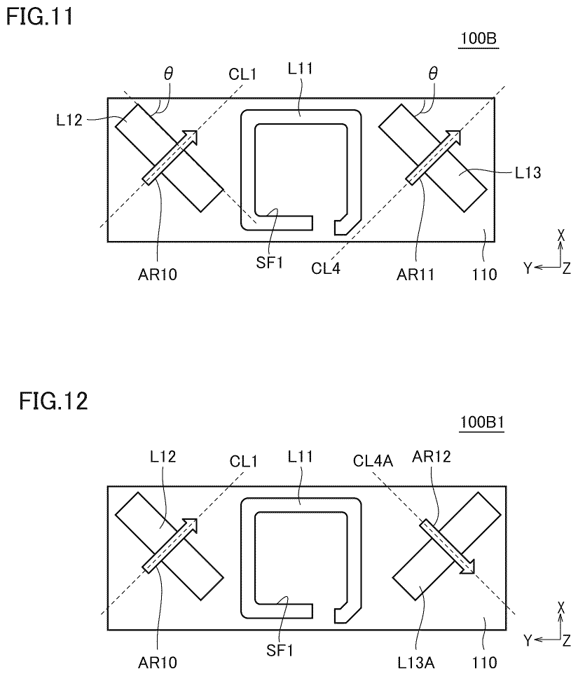

The following describes examples of an arrangement of inductors in filter FLT1A on the low-band side included in the filter device according to the second example embodiment with reference to FIGS. 11 to 13.

### First Example

FIG. 11 is a plan view of an arrangement of coils in filter FLT1A of filter device 100B according to a first example of the second example embodiment. In FIG. 11, the region of filter FLT1A in dielectric 110 is rectangular or substantially rectangular, and three inductors are arranged in the order of inductors L12, L11, and L13 in the Y-axis direction along the long side of the region. Inductor L11 is a planar coil, and inductors L12 and L13 are vertical coils.

As in filter FLT1 in the first example embodiment, inductor L12 is arranged so as to satisfy the relationship of about 0°≤0≤ about 45° with respect to the direction in which the inductors are arranged (the Y-axis direction). Imaginary line CL1 drawn to extend in the winding direction (an arrow AR10) of inductor L11 does not intersect with inner surface SF1 and the body of inductor L11 and inductor L13.

As in inductor L12, inductor L13 is also arranged so as to satisfy the relationship of about 0°≤θ≤about 45° with respect to the direction in which the inductors are arranged. An imaginary line CL4 drawn to extend in the winding direction (an arrow AR11) of inductor L13 does not intersect with inner surface SF1 and the body of inductor L11 and inductor L12.

As described above, also in the case in which the filter includes two vertical coils and one planar coil as inductors, the coils are arranged such that the winding axis direction of each vertical coil does not intersect with the planar coil, and thus, the robustness against the positional deviation of each vertical coil can be improved.

### Second Example

FIG. 12 is a plan view of an arrangement of coils in filter FLT1A of a filter device 100B1 according to a second example of the second example embodiment. As in filter device 100B in FIG. 11, also in filter device 100B1, the region of filter FLT1A in dielectric 110 is rectangular or substantially rectangular, and three inductors are arranged in the order of inductors L12, L11, and L13A in the Y-axis direction along the long side of the region. Inductor L11 is a planar coil, and inductors L12 and L13A are vertical coils.

In filter device 100B1, inductors L11 and L12 are arranged in the same or substantially the same manner as in FIG. 11. Inductor L13A is arranged at a position to which inductor L13 in FIG. 11 has been rotated by about 90° around the normal line (the Z axis) of dielectric 110.

Also in this case, an imaginary line CL4A drawn to extend in the winding direction (an arrow AR12) of inductor L13A does not intersect with inner surface SF1 and the body of inductor L11, and inductor L12. Also, imaginary line CL1 drawn to extend in the winding direction (arrow AR10) of inductor L11 does not intersect with inner surface SF1 and the body of inductor L11 and inductor L13A.

Also in filter device 100B1 in which the coils are arranged as in the second example, the coils are arranged such that the winding axis direction of each vertical coil does not intersect with the planar coil, and thus, the robustness against the positional deviation of each vertical coil can be improved.

### Third Example

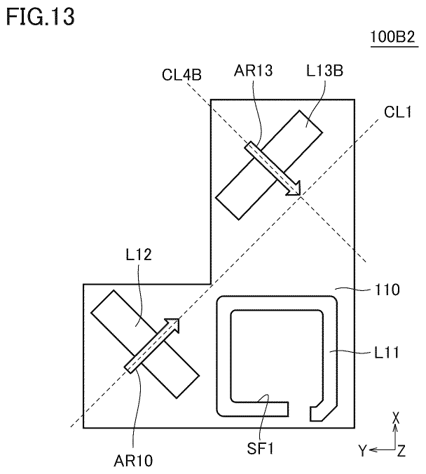

FIG. 13 is a plan view of an arrangement of coils in filter FLT1A of a filter device 100B2 according to a third example of the second example embodiment. In filter device 100B2, the region of filter FLT1A in dielectric 110 has an L or substantially L shape, and an inductor L13B is arranged in a direction (in the X-axis direction) orthogonal or substantially orthogonal to the direction (the Y-axis direction) in which inductors L12 and L11 are arranged with respect to inductor L11.

An imaginary line CL4B drawn to extend in the winding direction (an arrow AR13) of inductor L13B does not intersect with inner surface SF1 and the body of inductor L11 and inductor L12. Further, imaginary line CL1 drawn to extend in the winding direction (arrow AR10) of inductor L12 does not intersect with inner surface SF1 and the body of inductor L11 and inductor L13B.

Also in filter device 100B2 in which the coils are arranged as in the third example, the coils are arranged such that the winding axis direction of each vertical coil does not intersect with the planar coil, and thereby, the robustness against the positional deviation of each vertical coil can be improved.

In the configuration example in FIG. 13, imaginary line CL1 of inductor L12 does not intersect with inductor L13B, but imaginary line CL1 may intersect with inductor L13B as long as imaginary line CL4B of inductor L13B does not overlap with inductor L11. In this case, the effect of the variations in characteristics slightly decreases, but the magnetic coupling between the planar coil and the vertical coils is reduced or prevented, so that the advantageous effect of reducing the variations to a certain extent can be achieved.

Each of “inductors L13, L13C, and L13D” in the second example embodiment corresponds to the “third inductor”.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device comprising:
a dielectric including a main surface; and
a first filter in the dielectric; wherein
the first filter includes a first inductor and a second inductor inside the dielectric;
the first inductor includes a first coil with a winding axis corresponding to a normal direction to the main surface of the dielectric;
the second inductor includes a second coil including:
a first flat-plate electrode in the dielectric and extending linearly; and
a via connected to the first flat-plate electrode and extending in the normal direction of the dielectric; and
in a plan view seen from the normal direction of the dielectric, a first imaginary line does not intersect with an inner surface of the first coil, the first imaginary line being drawn from a center position in an extending direction of the first flat-plate electrode in the second inductor to extend in a direction orthogonal or substantially orthogonal to the extending direction.

2. The filter device according to claim 1, wherein the first imaginary line does not intersect with the first inductor in a plan view seen from the normal direction of the dielectric.

3. The filter device according to claim 1, wherein
in the plan view seen from the normal direction of the dielectric, the first inductor and the second inductor are adjacent to each other in a first direction; and
the extending direction of the first flat-plate electrode is inclined with respect to the first direction in the dielectric.

4. The filter device according to claim 3, wherein the extending direction of the first flat-plate electrode extends at about 0° or more and about 45° or less with respect to the first direction.

5. The filter device according to claim 1, wherein the first inductor has a longer line length than the second inductor.

6. The filter device according to claim 1, wherein a number of turns of the second inductor is one turn or less.

7. The filter device according to claim 1, wherein
the first filter includes an input terminal and an output terminal in the dielectric; and
in the first filter, the first inductor and the second inductor are positioned in order of the first inductor and the second inductor along a signal path extending from the input terminal to the output terminal.

8. The filter device according to claim 1, wherein
the first filter includes a third inductor inside the dielectric;
the third inductor includes a second coil including:
a second flat-plate electrode in the dielectric and extending linearly; and
a via connected to the second flat-plate electrode and extending in the normal direction of the dielectric; and
in a plan view seen from the normal direction of the dielectric, a second imaginary line does not intersect with the inner surface of the first coil, the second imaginary line being drawn from a center position in an extending direction of the second flat-plate electrode in the third inductor to extend in a direction orthogonal or substantially orthogonal to the extending direction.

9. The filter device according to claim 8, wherein the first imaginary line does not intersect with the third inductor.

10. The filter device according to claim 8, wherein
the first filter includes an input terminal and an output terminal in the dielectric; and
in the first filter, the second inductor, the first inductor, and the third inductor are positioned in order of the second inductor, the first inductor, and the third inductor along a signal path extending from the input terminal to the output terminal.

11. The filter device according to claim 1, wherein the first filter is a low-pass filter or a band-pass filter.

12. The filter device according to claim 1, further comprising:
a second filter in the dielectric; wherein
a frequency in a passband in the second filter is higher than a frequency in a passband in the first filter.

13. The filter device according to claim 12, wherein the second filter is a high-pass filter or a band-pass filter.

14. A filter device comprising:
a dielectric including a main surface;
a first filter in the dielectric and having a first passband; and
a second filter in the dielectric and having a second passband higher in frequency than the first passband; wherein
the first filter includes a first inductor and a second inductor inside the dielectric;
the first inductor includes a first coil with a winding axis corresponding to a normal direction to the main surface of the dielectric;
the second inductor includes a second coil including:
a first flat-plate electrode in the dielectric and extending linearly extending; and
a via connected to the first flat-plate electrode and extending in a normal direction of the dielectric; and
in a plan view seen from the normal direction of the dielectric, an imaginary line does not intersect with an inner surface of the first coil, the imaginary line being drawn from a center position in an extending direction of the first flat-plate electrode in the second inductor to extend in a direction orthogonal or substantially orthogonal to the extending direction.

15. A radio-frequency front end circuit comprising the filter device according to claim 1.

16. The radio-frequency front end circuit according to claim 15, wherein the first imaginary line does not intersect with the first inductor in a plan view seen from the normal direction of the dielectric.

17. The radio-frequency front end circuit according to claim 15, wherein
in the plan view seen from the normal direction of the dielectric, the first inductor and the second inductor are adjacent to each other in a first direction; and
the extending direction of the first flat-plate electrode is inclined with respect to the first direction in the dielectric.

18. The radio-frequency front end circuit according to claim 17, wherein the extending direction of the first flat-plate electrode extends at about 0° or more and about 45° or less with respect to the first direction.

19. The radio-frequency front end circuit according to claim 15, wherein the first inductor has a longer line length than the second inductor.

20. A radio-frequency front end circuit comprising the filter device according to claim 14.
